(19) United States
(12) Patent Application Publication
(10) Pub. No.: US 2026/0261213 A1
(43) Pub. Date: Sep. 3, 2026

(54) POWER ELECTRONICS ASSEMBLY

(71) Applicant: MAGNA Powertrain GmbH & Co KG, Lannach (AT)

(72) Inventors: Danijel Matesic, Guenselsdorf (AT); Peter Woller, Wien (AT)

(21) Appl. No.: 19/139,571

(22) PCT Filed: Dec. 15, 2023
(86) PCT No.: PCT/EP2023/086011

§ 371 Date: Jun. 16, 2025

(30) Foreign Application Priority Data
Dec. 22, 2022 (DE) 10 2022 214 272.1

(51) Int. Cl. H02M 7/00; H05K 1/182; H05K 3/00; H05K 3/325

(52) U.S. Cl. CPC H02M 7/003; H05K 1/182; H05K 3/0014; H05K 3/325; H05K 2201/10272; H05K 2201/10409; H05K 2203/0228

(57) ABSTRACT

A power electronics assembly, in particular an inverter, includes a DC link capacitor having a positive high-voltage busbar and a negative high-voltage busbar, and includes a printed circuit board assembly having a printed circuit board which is fitted with semiconductor components, which form half-bridge modules in particular, wherein the printed circuit board itself has at least one flexible projection, wherein the projection, at the end of the projection, is electrically conductively fastened directly to the positive high-voltage busbar or to the negative high-voltage busbar by a fastening member.

### CROSS-REFERENCE TO RELATED APPLICATIONS

This application is a National Stage of International Application No. PCT/EP2023/086011, filed Dec. 15, 2023 which claims priority to DE 10 2022 214 272.1, filed Dec. 22, 2022. The entire disclosures of each of the above applications are incorporated herein by reference.

### FIELD

The present disclosure relates to a power electronics assembly, in particular an inverter.

### BACKGROUND

This section provides information related to the present disclosure which is not necessarily prior art.

It is known that power electronics assemblies such as, in particular, inverters, can use a DC-link capacitor, also called an intermediate circuit capacitor, to stabilize a direct voltage and to limit direct voltage fluctuations which occur in inverters because of the required fast switching. Such DC-link capacitors can be produced using various technologies, for example as aluminum-electrolyte, film or ceramic capacitors. They are usually electrically conductively connected to two busbars, so-called “HV busbars”, specifically to a positive high-voltage busbar (HV+) and a negative high-voltage busbar (HV−).

Power electronic assemblies of this type such as, in particular, inverters, usually also include a printed circuit board assembly (PCBA) having a printed circuit board (PCB), which is fitted with semiconductor components which, in particular, form half-bridge modules. As a rule, inverters include a plurality of half-bridges which, on a DC side, are connected in parallel to the intermediate circuit capacitor. On an AC side, the half-bridges can be connected to an electric machine, for which a multi-phase alternating current can be provided by the inverter.

The necessary electric connections between the printed circuit board assembly and the DC-link capacitor are usually produced via wires and plugs. However, the mounting of plugs, wires and additional cable terminals on the high-voltage busbars is complicated and difficult to automate. Connecting the plugs is not possible with automatic pick-and-place machines. Manual work has to be incorporated into the production process. Thus, additional production steps are necessary, the work is not contamination-free, technical cleanliness cannot readily be guaranteed and the risk of damaging the PCBA, i.e. the printed circuit board assembly, is high.

### SUMMARY

This section provides a general summary of the disclosure, and is not a comprehensive disclosure of its full scope or all of its features.

It is an object of the present disclosure to specify a power electronics assembly, in particular an inverter, which avoids the above-described problems and in particular can be produced automatically, simply and inexpensively.

The object is achieved by a power electronics assembly, in particular an inverter, including a DC-link capacitor with a positive high-voltage busbar (HV+ busbar) and a negative high-voltage busbar (HV− busbar), and includes a printed circuit board assembly (PCBA) having a printed circuit board (PCB), which is fitted with semiconductor components which, in particular, form half-bridge modules, wherein the printed circuit board itself has at least one flexible projection, wherein the projection is electrically conductively directly fastened to the positive high-voltage busbar or to the negative high-voltage busbar by a fastening member at the end of the projection.

According to the present disclosure, a printed circuit board assembly, and therefore the semiconductor components on the printed circuit board, are electrically conductively connected to a DC-link capacitor, i.e. an intermediate circuit capacitor, wherein at least one projection, preferably two projections, of the printed circuit board itself are fastened to the busbars of the DC-link capacitor. The projections are formed on the printed circuit board itself, i.e. in one piece with the printed circuit board. In order that deviations can be accommodated by the projection at least in a z direction, i.e. in a vertical direction, without any risk that the printed circuit board is damaged in the process, the projection or the projections are flexible. Preferably, a projection is designed to be so flexible that it is able to compensate for +0.50 mm vertical tolerance.

Because the connection is implemented as part of the PCBA itself—other conventional parts such as plugs, wires or cable terminals are part of the PCBA itself—the production of the power electronics assembly is possible particularly inexpensively and in an automatic process, with less risk of contaminants.

Developments of the present disclosure are specified throughout the disclosure, the description, and the appended drawings.

Preferably, the projection of the printed circuit board has at least a U shape, S shape or serpentine shape. The production of a U shape, S shape or serpentine shape is very inexpensively possible and can be part of the usual PCBA production process.

The projection is preferably flat, with the same height which the printed circuit board also generally has in other regions.

Preferably, the printed circuit board has two flexible projections, wherein one of the projections is electrically conductively fastened to the positive high-voltage busbar by a fastening member at the end of the projection, and the other projection is electrically conductively fastened to the negative high-voltage busbar by a fastening member at the end of the projection.

Preferably, the two projections point in mutually opposite directions.

The fastening member is preferably a screw.

Additionally or alternatively, the projection can be clamped to the high-voltage busbar.

The end of the projection preferably has a screw hole.

Preferably, the end of the projection is designed to prevent rotation of the end of the projection. In particular, the end of the projection can have a rotation-preventing stop. By this arrangement, undesired rotation of the projection during fastening of the projection, in particular during screw fixing, is to be prevented.

Preferably, the printed circuit board and the projection of the printed circuit board have a contour which is designed such that the contour can be produced by using a common tool in a PCBA process. The projection is thus preferably cut out of the blank of the printed circuit board, particularly preferably in a single process and by using a single tool for the entire contour of the printed circuit board.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

The drawings described herein are for illustrative purposes only of selected embodiments and not all possible implementations, and are not intended to limit the scope of the present disclosure.

FIG. 1 is a three-dimensional illustration of a detail of a power electronics assembly according to the invention.

FIG. 2a is a schematic illustration from above of a detail of the printed circuit board of a power electronics assembly according to the invention according to FIG. 1.

FIG. 2b is a schematic detailed illustration from above of a detail of the printed circuit board according to FIG. 2a.

### DETAILED DESCRIPTION

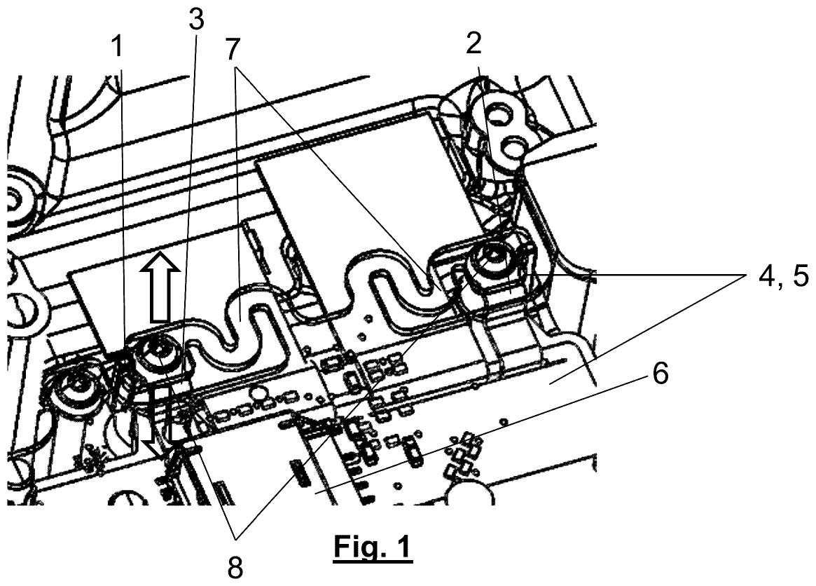

FIG. 1 illustrates the power electronics assembly according to the invention in a detail.

The power electronics assembly, specifically an inverter, includes a DC-link capacitor 1 having a positive high-voltage busbar 2 (HV+ busbar) and a negative high-voltage busbar 3 (HV− busbar) and also a printed circuit board arrangement 4 (PCBA) having a printed circuit board 5 (PCB) which is fitted with semiconductor components 6 which form half-bridge modules.

The printed circuit board 5 itself has two flexible projections 7, wherein one of the projections 7 is electrically conducted fastened to the positive high-voltage busbar 2 by a fastening member 8, specifically by a screw, at the end of the projection 7, and the other projection 7 is electrically conductively fastened to the negative high-voltage busbar 3 by a fastening member 8, specifically a further screw, at the end of the projection 7.

Each of the projections 7 of the printed circuit board 5 has a serpentine shape. The two projections 7 are each flat, with a thickness corresponding to the thickness of the printed circuit board 5. The two projections 7 lie in the same plane as the remainder of the printed circuit board 5. The two projections 7 point in mutually opposite directions. As a result of the flexible design of the projections 7, in particular as a result of the serpentine shape of the projections 7, these permit tolerance compensation of the ends of the projections 7 in the vertical direction (illustrated by arrows in FIG. 1). Preferably, the tolerance in the vertical direction (z direction) can be greater than 0.3 mm, for example about +/−0.5 mm. Depending on the design of the projection 7, a desired tolerance can also be achieved in the other directions, i.e. in the x and y directions.

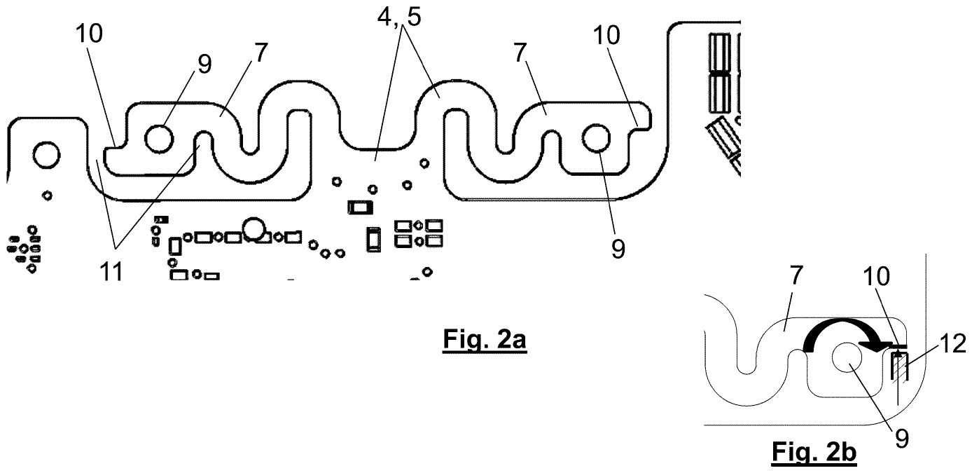

The projections are illustrated in more detail in FIG. 2a, and the ends of the projections in FIG. 2b. The end of each projection 7 has a screw hole 9 to receive the fastening member 8.

In addition, the end of each projection 7 is designed to prevent rotation of the end of the projection 7, specifically by a rotation-preventing stop 10.

The end of a projection 7 is illustrated in more detail in FIG. 2b. The rotation-preventing stop 10 is arranged in the power electronics assembly in such a way that in the event of rotation of the projection 7, at least in the envisaged direction of the screw fixing—illustrated as an arrow in FIG. 2b—with a screw as fastening member in the screw hole 9, it strikes a component 12 of the power electronics assembly and prevents rotation of the projection 7.

As illustrated in FIG. 2a, the printed circuit board 5 and the projection 7 of the printed circuit board 5 have a contour which is designed such that the contour can be produced by using a common tool 11 in a PCBA process.

### LIST OF REFERENCE SIGNS

1 DC-link capacitor
2 Positive high-voltage busbar (HV+)
3 Negative high-voltage busbar (HV−)
4 Printed circuit board assembly (PCBA)
5 Printed circuit board (PCB)
6 Semiconductor components
7 Projection
8 Fastening member, screw
9 Screw hole
10 Rotation-preventing stop
11 Tool
12 Component

What is claimed is:

1. A power electronics assembly, comprising;
a DC-link capacitor having a positive high-voltage busbar and a negative high-voltage busbar, the DC link capacitor including a printed circuit board assembly having a printed circuit board fitted with semiconductor components, wherein the semiconductor components form half-bridge modules,
wherein printed circuit board includes at least one flexible projection,
wherein the projection of the printed circuit board is electrically conductively directly fastened to the positive high-voltage busbar or to the negative high-voltage busbar by a fastening member disposed at the end of the projection.

2. The power electronics assembly as claimed in claim 1,
wherein the projection of the printed circuit board has at least a U shape, S shape, or serpentine shape.

3. The power electronics assembly as claimed in claim 1,
wherein the printed circuit board has two flexible projections, wherein a first projection of the projections is electrically conductively fastened to the positive high-voltage busbar by a fastening member at the end of the first projection, and a second projection projection of the is electrically conductively fastened to the negative high-voltage busbar by a fastening member at the end of the second projection.

4. The power electronics assembly as claimed in claim 3,
wherein the first and second projections point in mutually opposite directions.

5. The power electronics assembly as claimed in claim 1,
wherein the fastening member is a screw.

6. The power electronics assembly as claimed in claim 5,
wherein the end of the projection has a screw hole.

7. The power electronics assembly as claimed in claim 1,
wherein the end of the projection prevents rotation of the end of the projection.

8. The power electronics assembly as claimed in claim 1,
wherein the printed circuit board and the projection of the printed circuit board have a contour produced by using a common tool in a PCBA process.

9. The power electronics assembly of claim 8, wherein the printed circuit board and projection are formed as a single piece and are integral with each other.

10. The power electronics assembly as claimed in claim 7, wherein the end of the projection includes a rotation-preventing stop.

11. The power electronics assembly as claimed in claim 10, wherein the stop contacts a component of the power electronics assembly in the direction of rotation of the fastening member to block rotation of the projection in the same direction as the fastening member.

12. The power electronics assembly as claimed in claim 1, wherein the projection is flat and formed from a common blank with the printed circuit board, wherein the projection has the same height which the printed circuit board also has in other regions.

13. The power electronics assembly as claimed in claim 12, wherein the projection and the remainder of the printed circuit board lie in the same plane.

14. The power electronics assembly as claimed in claim 1, wherein the projection is flexible relative to the remainder of the printed circuit board in a Z-direction that is normal to the plane of the printed circuit board.

15. The power electronics assembly as claimed in claim 14, wherein the projection is further flexible in the X-direction and Y-direction, each of which are in plane with the printed circuit board.
